(19) United States
(12) Patent Application Publication
(10) Pub. No.: US 2007/0190789 A1
(43) Pub. Date: Aug. 16, 2007

(54) Compositions and methods for CMP of indium tin oxide surfaces

(76) Inventors: Phillip Carter, Round Lake, IL (US); Nevin Naguib, Aurora, IL (US); Fred F. Sun, Naperville, IL (US)

Correspondence Address: STEVEN WESEMAN;ASSOCIATE GENERAL COUNSEL, I.P., CABOT MICROELECTRONICS CORPORATION, 870 NORTH COMMONS DRIVE, AURORA, IL, 60504, US

(21) Appl. No.: 11/706,929

(22) Filed: Feb. 14, 2007

Related U.S. Application Data
(60) Provisional application No. 60/773,105, filed on Feb. 14, 2006.
(60) Provisional application No. 60/830,234, filed on Jul. 12, 2006.

(51) Int. Cl. H01L 21/461; C03C 15/00

(52) U.S. Cl. 438/692; 216/88; 252/79.1; 438/693

(57) ABSTRACT

The present invention provides chemical-mechanical polishing (CMP) compositions and methods for polishing an ITO surface. The compositions of the invention comprise a particulate zirconium oxide or colloidal silica abrasive, which has a mean particle size of not more than about 150 nm, suspended in an aqueous carrier, which preferably has a pH of not more than about 5. Preferably, the abrasive has a surface area in the range of about 40 to about 220 m²/g. The CMP compositions of the invention provide an acceptably low surface roughness when used to polish an ITO surface, providing clean and uniform surfaces.

### CROSS-REFERENCE TO RELATED APPLICATIONS

This application claims the benefit of U.S. Provisional Application for Patent Ser. No. 60/773,105, filed on Feb. 14, 2006, and U.S. Provisional Application for Patent Ser. No. 60/830,234, filed on Jul. 12, 2006, which are incorporated herein by reference.

### FIELD OF THE INVENTION

This invention relates to polishing compositions and methods for polishing a substrate using the same. More particularly, this invention relates to chemical-mechanical polishing compositions suitable for polishing substrates comprising indium tin oxide (ITO) and CMP methods utilizing the compositions.

### BACKGROUND OF THE INVENTION

Thin films of indium tin oxide (“ITO”) are highly conductive, and have a high light transmittance. Flat panel display devices typically utilize a thin layer of ITO substantially covering a flat panel surface. The ITO layer is configured to have an equipotential surface and an electrical conductivity lower than that of a solid metallic sheet. ITO is also used as a transparent electrode to construct organic light emitting diode (OLED) devices, as a window material for solar cells, and as an antistatic film.

The typically high surface roughness of ITO, along with non-uniformities, such as spikes, scratches, and surface residues (foreign materials adsorbed on the ITO surface) provide pathways for current leakage to flow through diodes adjacent to the ITO layer, resulting in cross-talk and undesirably low resistance. Cross-talk can have a direct impact on device performance, both electrically and optically. A smooth clean surface on the ITO layer is needed to minimize the level of unstable pixel-generating cross-talk in ITO devices, and to minimize leakage current. Reducing non-uniformities in the ITO surface provides an improvement in the overall performance, and thus better image quality in flat panel systems.

Compositions and methods for chemical-mechanical polishing (CMP) the surface of a substrate are well known in the art. Polishing compositions (also known as polishing slurries, CMP slurries, and CMP compositions) for CMP of metal-containing surfaces of semiconductor substrates (e.g., integrated circuits) typically contain an oxidizing agent, various additive compounds, abrasives, and the like.

In conventional CMP techniques, a substrate carrier or polishing head is mounted on a carrier assembly and positioned in contact with a polishing pad in a CMP apparatus. The carrier assembly provides a controllable pressure (“down force”) to the substrate, urging the substrate against the polishing pad. The pad is moved relative to the carrier, with attached substrate, which serves to abrade the surface of the substrate to remove a portion of the material from the substrate surface, thereby polishing the substrate. The polishing of the substrate surface typically is further aided by the chemical activity of the polishing composition (e.g., by oxidizing agents present in the CMP composition) and/or the mechanical activity of an abrasive suspended in the polishing composition. Typical abrasive materials include silicon dioxide, cerium oxide, aluminum oxide, zirconium oxide, and tin oxide.

Several methods have been proposed for reducing non-uniformities in ITO surfaces, including polishing, surface treatments (e.g., plasma treatment), as well as controlled ITO deposition techniques. One polishing method that has been proposed to improve ITO surface uniformity is dry-polishing with a fixed abrasive pad or tape. Fixed abrasive pads typically create undesirable scratches on the ITO surface. Chemical mechanical polishing (CMP) has also been investigated to reduce ITO surface roughness, although the existing methods still leave room for improvement.

There is an ongoing need to develop new CMP compositions that exhibit reduced scratching and residue defects, and lower surface roughness in polishing of indium tin oxide, compared to conventional polishing methods. The present invention provides such improved CMP compositions and methods. These and other advantages of the invention, as well as additional inventive features, will be apparent from the description of the invention provided herein

### BRIEF SUMMARY OF THE INVENTION

The present invention provides chemical-mechanical polishing (CMP) compositions and methods for polishing an ITO surface. The CMP compositions of the invention comprise a particulate zirconium oxide (ZrO₂) or colloidal silica (SiO₂) abrasive having a mean particle size of not more than about 150 nm, as determined by light scattering. The abrasive is suspended in an aqueous carrier (e.g., deionized water), which preferably has a pH of not more than about 5. The abrasive particles preferably have a surface area in the range of about 40 to about 220 m²/g, as determined by gas adsorption using the Brunauer-Emmett-Teller (BET) method, which is well known in the art (see S. Brunauer, P. H. Emmett, and E. Teller, J. Am. Chem. Soc., 1938, 60, 309).

In a preferred embodiment, compositions of the invention comprise a particulate zirconium oxide abrasive having a mean particle size of not more than about 150 nm (preferably not more than about 100 nm) and a surface area in the range of about 40 to about 75 m²/g. The zirconium oxide abrasive is suspended in an aqueous carrier, which preferably has a pH of not more than about 5, more preferably not more than about 3.

In another preferred embodiment, compositions of the invention comprise a particulate colloidal silica abrasive having a mean particle size in the range of about 20 to about 140 nm, preferably having a surface area in the range of about 80 to about 220 m²/g, as determined by gas adsorption using the BET method. The colloidal silica abrasive is suspended in an aqueous carrier, which preferably has a pH of not more than about 5, more preferably not more than about 3.

The CMP compositions of the invention provide a significantly lower surface roughness when used to polish an ITO surface, compared to the results obtained with CMP compositions comprising ceria or alumina, for example.

The present invention also provides a method of polishing a surface of an ITO substrate utilizing a CMP composition of the invention. A preferred method comprises the steps of contacting a surface of an ITO-containing substrate with a polishing pad and an aqueous CMP composition of the invention, and causing relative motion between the polishing pad and the substrate, while maintaining a portion of the CMP composition in contact with the surface between the pad and the substrate. The relative motion is maintained for a period of time sufficient to abrade at least a portion of the ITO from the surface of the substrate.

### DETAILED DESCRIPTION OF THE INVENTION

The present invention provides CMP compositions useful for polishing an indium tin oxide (ITO) surface. The CMP compositions of the invention provide for even removal of an ITO with reduced surface roughness relative to conventional CMP compositions. The CMP compositions contain a particulate zirconium oxide or colloidal silica abrasive material suspended in an aqueous carrier. The particulate abrasive material has a mean particle size of not more than about 150 nm, as determined by laser light scattering techniques. The abrasive particles preferably have a surface area, as determined by BET gas adsorption, in the range of about 40 to about 220 m²/g. In preferred embodiments, the pH of the aqueous carrier is not more than about 5, more preferably not more than about 3.

In one preferred embodiment, the CMP composition comprises a particulate zirconium oxide abrasive having a particle size of not more than about 150 nm, preferably not more than about 100 nm, and a BET surface area in the range of about 40 to about 75 m²/g. The zirconium oxide abrasive is suspended in an aqueous carrier, which preferably has a pH of not more than 5, preferably not more than 3. In addition, the zirconium oxide abrasive can optionally comprise about 0.5 to about 5 percent by weight of yttrium oxide (Y₂O₃).

While not wishing to be bound by theory, it is believed that an acidic pH is beneficial when using the zirconium oxide abrasive, in particular, because the zeta potentials of ITO and of zirconium oxide are both positive at low pH (e.g., less than about pH 5). The positive zeta potential of the zirconium particles causes the particles to be slightly repelled by the positive ITO surface. The repulsion between the particles and the ITO surface beneficially affords reduced levels of scratching, a reduced amount of adhering zirconia particles on the surface, and improved cleanability of the ITO surface.

In another preferred embodiment, the CMP composition comprises a particulate colloidal silica abrasive having a particle size in the range of about 20 to about 140 nm. The colloidal silica preferably has a BET surface area in the range of about 80 to about 220 m²/g. The silica abrasive is suspended in an aqueous carrier, which preferably has a pH of not more than 5, more preferably not more than 3.

The crystal structure of colloidal silica likely contributes to its effectiveness for polishing ITO, particularly compared to the performance of fumed silica. Fumed silica tends to have particles with relatively sharp edges, which can lead to scratching when used to polish ITO surfaces. In contrast, colloidal silica has a more uniform particle size distribution and smoother surface than fumed silica, which may contribute, at least in part, to the improved ITO surface roughness observed after polishing with colloidal silica-based composition of the invention.

Preferably, the abrasive material is present in the compositions of the invention in an amount in the range of about 0.1 to about 10 percent by weight, more preferably in the range of about 0.5 to about 5 percent by weight.

The abrasive is suspended in the in the aqueous carrier component of the CMP composition and preferably is colloidally stable in the carrier. The term colloid, as used herein, refers to the suspension of abrasive particles in the liquid carrier. Colloidal stability refers to the maintenance of that suspension over time. In the context of this invention, an abrasive is considered colloidally stable if, when the abrasive is placed into a 100 mL graduated cylinder and allowed to stand without agitation for a time of 2 hours, the difference between the concentration of particles in the bottom 50 mL of the graduated cylinder ([B] in terms of g/mL) and the concentration of particles in the top 50 mL of the graduated cylinder ([T] in terms of g/mL) divided by the initial concentration of particles in the abrasive composition ([C] in terms of g/mL) is less than or equal to 0.5 (i.e., ([B]−[T])/[C]≦0.5). The value of ([B]−[T])/[C] desirably is less than or equal to 0.3, and preferably is less than or equal to 0.1.

The CMP compositions of the invention can have any suitable pH, generally in the range of about 2 to about 11. Preferably, the compositions have a pH of not more than about 5 (e.g., about 2 to about 5), more preferably not more than about 3. The CMP compositions can be adjusted to the desired pH value by addition of an acid or a base. For example, an inorganic acid, an organic acid or combination thereof, can be used to lower the pH, while a basic material, such as sodium hydroxide or an amine can be used to raise the pH. The aqueous solution may also contain a pH buffering agent to maintain the pH at the desired level. The pH buffering agent can be any suitable buffering agent, for example, phosphates, acetates, borates, sulfonates, carboxylates, ammonium salts, combinations thereof, and the like. The CMP compositions of the invention can comprise any suitable amount of pH adjustor or pH buffering agent, provided such amount is sufficient to achieve and/or maintain the desired pH.

The CMP compositions of the invention can include optional additive materials such as rheology modifiers, dispersants, chelating agents, biocides, and the like, so long as the additives do not cause undesirable aggregation of the abrasive particles or unfavorably affect surface roughness when used to polish ITO.

The CMP compositions of the invention can be prepared by any suitable technique, many of which are known to those skilled in the art. The CMP composition can be prepared in a batch or continuous process. Generally, the CMP composition can be prepared by combining the components thereof in any order. The term “component” as used herein includes individual ingredients (e.g., abrasives, acids, bases, buffers, and the like), as well as any combination of ingredients. For example, an abrasive can be dispersed in water, and any buffering agents or other additives can be added to the suspension, and mixed by any method that is capable of incorporating the components into the CMP composition. The pH can be adjusted at any suitable time, as needed.

The CMP compositions of the present invention also can be provided as a concentrate, which is intended to be diluted with an appropriate amount of water prior to use. In such an embodiment, the CMP composition concentrate can include the various components dispersed or dissolved in aqueous solvent in amounts such that, upon dilution of the concentrate with an appropriate amount of aqueous solvent, each component of the polishing composition will be present in the CMP composition in an amount within the appropriate range for use (e.g., to afford the desired pH level after dilution).

The invention also provides a method of chemically-mechanically polishing a substrate that includes an ITO surface. The preferred method comprises (i) contacting the ITO surface of the substrate with a polishing pad and a CMP composition of the invention as described herein, and (ii) moving the polishing pad relative to the surface of the substrate with the polishing composition therebetween, thereby abrading at least a portion of an ITO from the surface.

The CMP methods of the present invention are particularly suited for use in conjunction with a chemical-mechanical polishing apparatus. Typically, the CMP apparatus comprises a platen, which, when in use, is in motion and has a velocity that results from orbital, linear, and/or circular motion, a polishing pad in contact with the platen and moving with the platen when in motion, and a carrier that holds a substrate to be polished in contact with the pad and moving relative to the surface of the polishing pad. A CMP composition is typically pumped onto the polishing pad to aid in the polishing process. The polishing of the substrate is accomplished by the combined abrasive action of the moving polishing pad and the CMP composition of the invention present on the polishing pad, which abrades at least a portion of the surface of the substrate, and thereby polishes the surface.

A substrate can be planarized or polished with a CMP composition of the invention using any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof.

Desirably, the CMP apparatus further comprises an in situ polishing endpoint detection system, many of which are known in the art. Techniques for inspecting and monitoring the polishing process by analyzing light or other radiation reflected from a surface of the workpiece are known in the art. Such methods are described, for example, in U.S. Pat. No. 5,196,353 to Sandhu et al., U.S. Pat. No. 5,433,651 to Lustig et al., U.S. Pat. No. 5,949,927 to Tang, and U.S. Pat. No. 5,964,643 to Birang et al. Desirably, the inspection or monitoring of the progress of the polishing process with respect to a workpiece being polished enables the determination of the polishing end-point, i.e., the determination of when to terminate the polishing process with respect to a particular workpiece.

The following examples further illustrate the invention but, of course, should not be construed as in any way limiting its scope.

### EXAMPLE 1

This example illustrates the performance of conventional CMP compositions for removal of ITO from a substrate, compared to compositions of the invention.

Wafers (about 4 inches by 4 inches) having an ITO surface layer (about 1500 A of ITO deposited on a glass substrate) were polished on a Hyprez table-top polisher using a Betalap or FK-N1 polishing pad, with a platen speed of about 45-65 rpm, a carrier speed of about 40-60 rpm, a down force of about 0.3 to about 1.75 psi, and a slurry flow rate of 40 mL/minute. The CMP slurry compositions which were evaluated had the formulations shown below.

Slurry A—12% by weight of fumed silica (mean particle size of about 140 nm, surface area of about 90 m²/g) dispersed in deionized water. The pH of slurry was adjusted to 10 with potassium hydroxide.

Slurry B—5% by weight of colloidal silica (mean particle size of about 75 nm, surface area of about 80 m²/g), dispersed in deionized water. The pH of slurry was adjusted to 10 with potassium hydroxide.

Slurry C—0.5% by weight of ceria (mean particle size of about 80 nm, surface area of about 60 m²/g) dispersed in deionized water. The pH of slurry was adjusted to 2 with nitric acid.

Slurry D—0.5% by weight of ceria (mean particle size of about 80 nm, surface area of about 60 m²/g) dispersed in deionized water. The pH of slurry was adjusted to 5 with nitric acid.

Slurry E—0.5% by weight of ceria (mean particle size of about 80 nm, surface area of about 60 m²/g) dispersed in deionized water. The pH of slurry was adjusted to 10.5 with potassium hydroxide.

Slurry F—1% by weight of zirconia (mean particle size of about 150 nm, surface area of about 40 m²/g) dispersed in deionized water. The pH of slurry was adjusted to 5 with nitric acid.

Slurry G—1% by weight of zirconia (mean particle size of about 150 nm, surface area of about 40 m²/g) dispersed in deionized water. The pH of slurry was adjusted to 10.5 with potassium hydroxide.

Slurry H—1% by weight of alpha-alumina (mean particle size of about 130 nm, surface area of about 30-50 m²/g) dispersed in deionized water. The pH of slurry was adjusted to 4 with nitric acid.

Slurry I—1% by weight of alpha-alumina (mean particle size of about 130 nm, surface area of about 30-50 m 2/g) dispersed in deionized water. The pH of slurry was adjusted to 10.5 with potassium hydroxide.

Slurry J—5% by weight of colloidal silica (mean particle size of about 25 nm, surface area of about 200 m²/g) dispersed in deionized water. The pH of slurry was adjusted to 2.5 with nitric acid.

Slurry K—5% by weight of colloidal silica (mean particle size of about 40 nm, surface area of about 80 m²/g) dispersed in deionized water. The pH of slurry was adjusted to 2.5 with nitric acid.

Slurry L—5% by weight of colloidal silica (mean particle size of about 43 nm, surface area of about 130 m²/g) dispersed in deionized water. The pH of slurry was adjusted to 2.5 with nitric acid.

Slurry M—5% by weight of colloidal silica (mean particle size of about 20 nm, surface area of about 220 m²/g) dispersed in deionized water. The pH of slurry was adjusted to 2.5 with nitric acid.

Slurry N—0.5% by weight of zirconia (mean particle size of about 103 nm, surface area of about 60-75 m2/g) dispersed in deionized water. The pH of slurry was adjusted to 2.5 with nitric acid.

Slurry O—1.5% by weight of zirconia (mean particle size of about 103 nm, surface area of about 60-75 m²/g) dispersed in deionized water. The pH of slurry was adjusted to 2.5 with nitric acid.

Slurry P—3.0% by weight of zirconia (mean particle size of 103 nm, surface area of about 60-75 m²/g) dispersed in deionized water. The pH of slurry was adjusted to 2.5 with nitric acid.

The surface roughness of the ITO wafers was determined before and after polishing. The mean surface roughness values (Ra, nm) were determined by atomic force microscopy (AFM). Table 1 provides mean surface roughness values (Ra) for the center and edge of each wafer, and the observed percentage of improvement in roughness after polishing.

TABLE 1
Surface Roughness.

| | Roughness | Roughness (Ra, nm) | | Roughness |
|---|---|---|---|---|
| CMP | Measurement | pre- | post- | Improvement |
| Slurry | Location | polishing | polishing | (%) |
| Slurry A | Center | 1.19 | 0.66 | 44.3 |
| | Edge | 1.11 | 0.50 | 54.5 |
| Slurry B | Center | 1.10 | 0.82 | 25.3 |
| | Edge | 1.31 | 0.82 | 37.6 |
| Slurry C | Center | 1.29 | 0.36 | 72.0 |
| | Edge | 1.17 | 0.49 | 58.4 |
| Slurry D | Center | 1.06 | 0.49 | 54.0 |
| | Edge | 1.07 | 0.38 | 65.1 |
| Slurry E | Center | 0.99 | 0.60 | 39.3 |
| | Edge | 0.98 | 0.64 | 34.9 |
| Slurry F | Center | 1.12 | 0.44 | 60.6 |
| | Edge | 1.09 | 0.37 | 66.6 |
| Slurry G | Center | 1.03 | 0.43 | 58.7 |
| | Edge | 1.07 | 0.44 | 58.6 |
| Slurry H | Center | 1.03 | 0.44 | 57.7 |
| | Edge | 0.95 | 0.39 | 58.6 |
| Slurry I | Center | 1.23 | 0.88 | 28.0 |
| | Edge | 1.28 | 0.52 | 59.3 |
| Slurry J | Center | 1.00* | 0.33 | 66.6 |
| | Edge | 0.97* | 0.20 | 79.6 |
| Slurry K | Center | 1.00* | 0.25 | 75.0* |
| | Edge | 0.99* | 0.39* | 60.0* |
| Slurry L | Center | 1.00* | 0.54 | 46.0* |
| | Edge | 0.99* | 0.39* | 60.0* |
| Slurry M | Center | 1.00* | 0.39 | 60.0* |
| | Edge | 0.99* | 0.39* | 60.0* |
| Slurry N | Center | 1.178 | 0.190 | 83.87 |
| | Edge | 1.169 | 0.185 | 84.17 |
| Slurry O | Center | 1.237 | 0.249 | 79.87 |
| | Edge | 1.226 | 0.234 | 80.91 |
| Slurry P | Center | 1.190 | 0.203 | 82.94 |
| | Edge | 1.186 | 0.198 | 83.30 |

*estimated

In Table 1, the improvement in surface roughness was determined by taking the difference between the pre-polishing and post-polishing roughness, dividing by the pre-polishing roughness, and then multiplying by 100. The results in Table 1 indicate that the compositions of the invention comprising zirconium oxide (zirconia) or colloidal silica, and having a mean particle size of not more than about 150 nm, provided a significantly and unexpectedly greater improvement in surface roughness compared to the other compositions tested. This was particularly evident for compositions N, O, and P, which exhibited improvements of about 80% or greater, and post-polishing mean surface roughness values in that range of about 0.185 to about 0.243.

The light transmittance of the ITO wafer polished with composition J was also evaluated at three wavelengths: 700 nm (red), 530 nm (green), and 465 nm (blue). The transmittance at 700 nm went from about 83.1 percent (pre-polishing), to about 85.6 percent (post polishing). Similarly, the transmittance at 465 nm went from about 86 percent (pre-polishing), to about 89.8 percent (post polishing). The green light transmittance remained about the same (about 83.1 percent pre-polishing and about 82.2 percent post-polishing).

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A chemical-mechanical polishing (CMP) composition for polishing an indium tin oxide (ITO) surface, the composition comprising a particulate zirconium oxide or colloidal silica abrasive having a particle size of not more than about 150 nm, dispersed in an aqueous carrier.

2. The CMP composition of claim 1 wherein the abrasive is present in the composition in an amount in the range of about 0.1 to about 10 percent by weight.

3. The CMP composition of claim 1 wherein the abrasive has a surface area in the range of about 40 to about 220 m²/g.

4. The CMP composition of claim 1 wherein the aqueous carrier has a pH of not more than about 5.

5. A chemical-mechanical polishing (CMP) method for polishing an indium tin oxide (ITO) surface, the method comprising the steps of:
(a) contacting the ITO surface with a polishing pad and an aqueous CMP composition of claim 1, and
(b) causing relative motion between the polishing pad and the ITO surface while maintaining a portion of the CMP composition in contact with the ITO surface between the pad and the substrate for a time period sufficient to abrade at least a portion of the ITO from the surface.

6. A chemical-mechanical polishing (CMP) composition for polishing an indium tin oxide (ITO) surface, the composition comprising a particulate zirconium oxide abrasive having a particle size of not more than about 150 nm and a surface area in the range of about 40 to about 75 cm²/g, dispersed in an aqueous carrier.

7. The CMP composition of claim 6 wherein the abrasive is present in the composition in an amount in the range of about 0.1 to about 10 percent by weight.

8. The CMP composition of claim 6 wherein the aqueous carrier has a pH of not more than about 5.

9. A chemical-mechanical polishing (CMP) method for polishing an indium tin oxide (ITO) surface, the method comprising the steps of:
(a) contacting the ITO surface with a polishing pad and an aqueous CMP composition of claim 6, and
(b) causing relative motion between the polishing pad and the ITO surface while maintaining a portion of the CMP composition in contact with the ITO surface between the pad and the substrate for a time period sufficient to abrade at least a portion of the ITO from the surface.

10. A chemical-mechanical polishing (CMP) composition for polishing an indium tin oxide (ITO) surface, the composition comprising a particulate colloidal silica abrasive having a particle size in the range of about 20 to about 140 nm dispersed in an aqueous carrier.

11. The CMP composition of claim 10 wherein the abrasive is present in the composition in an amount in the range of about 0.1 to about 10 percent by weight.

12. The CMP composition of claim 10 wherein the aqueous carrier has a pH of not more than about 5.

13. The CMP composition of claim 10 wherein the abrasive has a surface area in the range of about 80 to about 220 m²/g.

14. A chemical-mechanical polishing (CMP) method for polishing an indium tin oxide (ITO) surface, the method comprising the steps of:
(a) contacting the ITO surface with a polishing pad and an aqueous CMP composition of claim 10, and
(b) causing relative motion between the polishing pad and the ITO surface while maintaining a portion of the CMP composition in contact with the ITO surface between the pad and the substrate for a time period sufficient to abrade at least a portion of the ITO from the surface.
